(19) United States
(12) Patent Application Publication
(10) Pub. No.: US 2005/0162674 A1
(43) Pub. Date: Jul. 28, 2005

(54) Downsized color printing apparatus

(76) Inventor: Naoyuki Yamada, Kanagawa-Ken (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/003,736

(22) Filed: Dec. 6, 2004

(30) Foreign Application Priority Data
Dec. 5, 2003 (JP) 2003-407057

(51) Int. Cl. G06F 15/00; G03F 3/08

(52) U.S. Cl. 358/1.9; 358/521

(57) ABSTRACT

In a color image forming apparatus, a first data transfer device provided in a main control unit transfers image data of component colors (e.g. CMYK) per a unit of a component color plate in a different timing from a first memory device having a capacity to store at least one page to a print control device provided in a print control unit. An image processing device provided in the print control unit performs image processing per the component color plate in a different timing, and stores the image data in a second memory having a capacity to store at least one page.

### COPYRIGHT NOTICE

A portion of the disclosure of this patent document contains material which is subject to copyright protection. The copyright owner has no objection to the facsimile reproduction of the patent document or the patent disclosure, as it appears in the Patent and Trademark Office patent file or records, but otherwise reserves all copyright rights whatsoever.

### CROSS-REFERENCE TO THE RELATED APPLICATION

This patent document claims priority under 35 USC § 119 to Japanese Patent Application No. 2003-407057 filed on Dec. 05, 2003, the entire contents of which are hereby incorporated by reference.

### BACKGROUND OF THE INVENTION

1. Field of the Invention

The present invention relates to various printing apparatuses, such as printers, copiers, facsimiles, etc.

2. Discussion of the Background Art

A printing apparatus such as a printer generally includes a main controller unit and a printing control unit (e.g. an engine driver). The printing control unit generally prints an image on a recording medium such as a sheet in accordance with image data, which is transmitted from the main controller unit. Japanese Patent Application Laid Open No. 9-314912 discusses such a printing apparatus in which image data of three plates of RGB (i.e., a triple color) or four plates of CMYK (i.e., a quartet color) are simultaneously transferred from the main control unit to the print control unit to print a color image at a high speed.

However, to print a color image at a high speed in such a printing apparatus, an image-processing device requires image-processing hardware for the respective four plates because image processing of the respective plates should be simultaneously performed. Further, it is costly because image data of the four plates, which has undergone image processing, should be stored at once, and accordingly, a memory capable of simultaneously storing the four plates is required.

### SUMMARY OF THE INVENTION

Accordingly, an object of the present invention is to address and resolve such and other problems and provide a new and novel color printing apparatus including a main control unit formed from a main control device that generally controls the printing apparatus, a first memory device that has a capacity to store at least one page of image data, and a first data transfer device that transfers image data of component colors per component color plate in turn to a print control unit. The print control unit includes a print control device that controls the print control unit, a second memory that has a capacity to store at least one page of image data, an image processing device that processes the image data, and a storage device that stores the image data having received the image processing.

In another exemplary embodiment, the image processing device includes a resolution conversion device that converts a resolution of the image data into a prescribed level.

In yet another exemplary embodiment, the printing control unit includes a reordering device that reorders the image data before printing.

In yet another exemplary embodiment, a print resolution designation device is provided to designate a printing resolution. In another exemplary embodiment, a memory capacity calculation device is provided to calculate an amount of image data likely stored in a second memory based upon the resolution. A memory control device is provided to control storage of the image data in the second memory in accordance with a calculation result of the memory capacity calculation device.

In yet another exemplary embodiment, a copy number designating device is provided to designate a number of copies. In another exemplary embodiment, a second memory control device is provided to read the same image data from the second memory as needed when the copy number designating device designates prescribed plural numbers of copies.

It is to be understood that both the foregoing general description and the following detailed description are exemplary, but are not restrictive of the invention.

### BRIEF DESCRIPTION OF THE DRAWINGS

A more complete appreciation of the present invention and many of the attendant advantages thereof will be readily obtained as the same becomes better understood by reference to the following detailed description when considered in connection with the accompanying drawings, wherein:

FIG. 1 depicts an exemplary configuration of an ink jet printing apparatus according to one embodiment of the present invention;

FIG. 2 depicts an exemplary method of controlling a color printing apparatus; and

FIG. 3 depicts a computer system upon which an embodiment of the present invention may be implemented.

### PREFERRED EMBODIMENTS OF THE PRESENT INVENTION

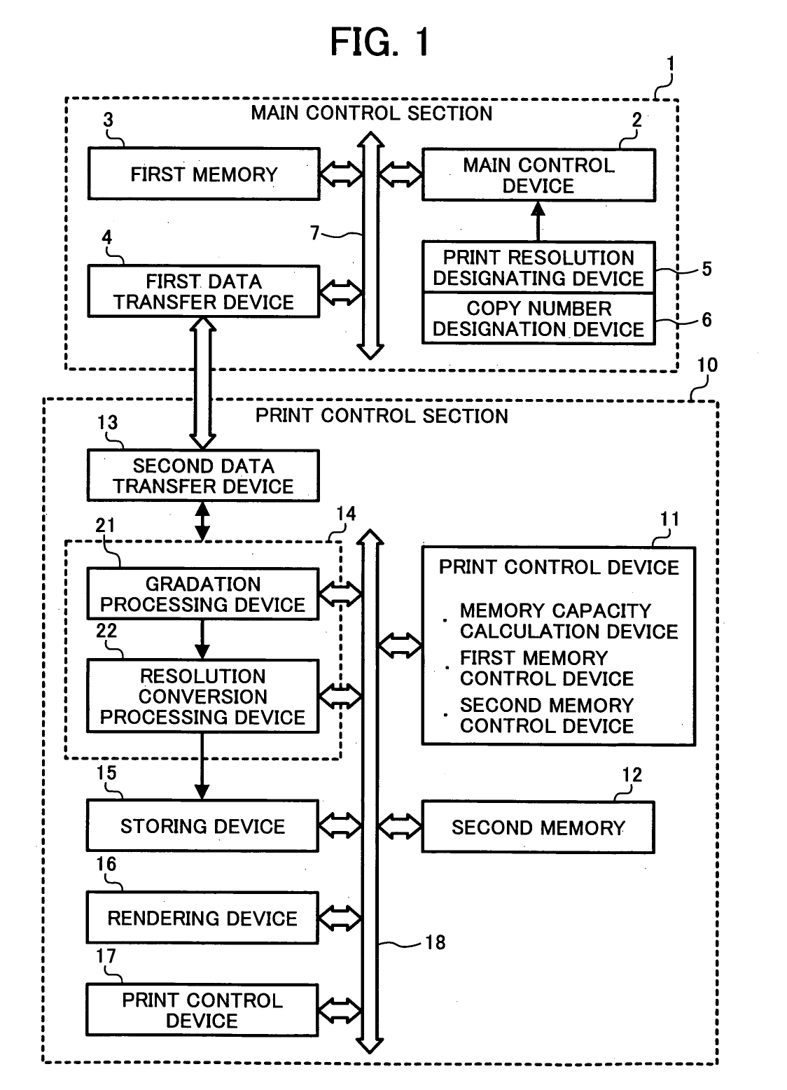

Referring now to the drawings, wherein like reference numerals designate identical or corresponding parts throughout several views, and in particular to FIG. 1, a configuration of an exemplary ink jet printing apparatus of one embodiment of the present invention is described.

The ink jet printing apparatus includes a main control unit 1 and a print control unit 10, which are mutually connected by a bus with each other. The main control unit 1 includes a main control device 2, a first memory device 3, a first data transfer device 4, a print resolution designation device 5, and a copy number designation device 6. Among those, the main control device 2, the first memory device 3, and the first data transfer device 4 are mutually connected by a bus 7 with each other.

The main control device 2 generally controls the entire ink jet printing apparatus. A function of the main control device 2 can be realized when a CPU (i.e., a microcomputer) reads and executes prescribed programs stored in a memory such as a ROM. The first memory device 3 is formed from a RAM, an HDD, or the like and has a capacity to store one page of image data (i.e., a unit of printing). Image data to be stored in the first memory device 3 can be generated from data such as character code data, depiction data, etc., which is transmitted from an external apparatus such as a personal computer (not shown).

The first data transfer device 4 can be constituted by a PCI bus, and communicates image data and control data with a print control unit 10. The print resolution designating device 5 designates a printing resolution in response to an operational signal generated by an operation through an operation panel (not shown). A function of the print resolution designating device 5 can be realized when the CPU reads and executes a prescribed program, which is stored in the memory. The copy number designating device 6 designates a number of copies in response to an operational signal generated by an operation through the operation panel. A function of the copy number designating device 6 can be realized when the CPU reads and executes the prescribed program, which is stored in the memory.

The print control unit 10 includes a print control device 11, a second memory device 12, a second data transfer device 13, an image processing device 14, a storage device 15, a rendering device 16, and a print control device 17. Among those, the print control device 11, the second memory device 12, the image processing device 14, the storage device 15, the rendering device 16, and the print control device 17 are mutually connected by a bus 18 with each other.

The print control device 11 includes a memory capacity calculation device, and first and second memory control devices to control the print control unit 10 to appropriately print. The first and second memory control devices control the second memory device 12. A function of the print control device 11 can be realized when the CPU reads and executes prescribed programs stored in the memory. The second memory device 12 is formed from a RAM, an HDD, or the like similar to the first memory device 3 and has a capacity to store at least one page of image data (i.e., a unit of printing).

The second memory device 12 has a capacity to store image data of substantially one page value of the maximum resolution. Thus, if the image data value is less than that of the maximum resolution, the second memory device 12 has a vacancy.

According to one embodiment, image data of a next page or plate is stored in the second memory device 12 before the previous printing is completed. Specifically, a calculation is performed to detect the vacancy based upon the capacity of the second memory device 12 and the resolution of the image data.

The second data transfer device 13 can be realized by a PCI bus or the like and communicates image data and control data to the main control unit 1. The image processing device 14 may include a gradation processing device 21 and a resolution conversion device 22 to apply image processing, which is suitable for printing, to image data in the unit of a page, which is transmitted from the main control unit 1 and is received by the second data transfer device 13. The gradation processing device 21 applies gradation processing to the incoming image data, which is suitable for the print engine. The resolution conversion device 22 converts a resolution of incoming image data to a prescribed level that enables the print engine to appropriately print (i.e., image formation).

The storage device 15 corresponds to a DMA (Direct Memory Access) control section, and transfers and stores image data, which has been processed by the image processing device 14, in the second memory device 12. The rendering device 16 applies rendering (i.e., reordering) to image data, which has been processed and is stored in the second memory device 12, to generate scan data suitable for an ink jet printing head. The print control device 17 controls the print engine to appropriately print an image on a printing medium or the like based upon the image data (i.e., scan data) having received the rendering.

In such a printing apparatus, when the print control unit 10 prints a color image based upon image data transmitted from the main control unit 1, the main control unit 1 separately transfers image data of each of four plates (e.g. CMYK) to the print control unit 10 per plate. Specifically, when the first data transfer device 4 transfers image data from the first memory device 3, which has a capacity to store at least one page, to the print control device 11 via the main control device 2, the image data is transferred in a unit of a page per component color, (i.e., respective plates are not simultaneously transferred) even if one page of a color image is transferred. That is, the image processing device 14 performs image processing per a component color, and stores the image data in the second memory device 12 having a capacity to store at least one page in a different timing. Accordingly, a plurality of image processing devices are not needed for respective component colors. Thus, a color image can be printed by an image processing device and a storage device where each only handles one plate value as in a printing of a monochrome image. The hardware can simultaneously be downsized.

Specifically, it is enough for the print control unit 10 to apply image processing to image data of one plate value, and the image processing device only needs image processing hardware of one plate value. Further, when image data having undergone image processing is to be stored, it is enough for a storage device 15 to have only one plate value. Further, although first and second memory devices storing image data of one page (i.e., a unit of printing) are needed, an undesirable processing interval can be reduced while downsizing hardware such as: an image processing device for printing, a memory device connected thereto, etc., if image data of each plate is transferred in a chronological order. Specifically, a color image can be printed by substantially the same scale device as a monochrome image.

The image processing device 14 and the image data transfer devices 4 and 13 are formed from a circuit, and preferably includes a circuit scale capable of dealing with image data of substantially one plate value.

Further, since the image processing device of the print control unit 10 includes the resolution conversion device that converts the resolution of incoming image data into a prescribed level that enables the print engine to appropriately print, image data such as facsimile data can be printed on a printing medium. Accordingly, a printing apparatus employing such an ink jet printing system can process and print image data such as facsimile data. Since the print control unit 10 employs the rendering device 16 that applies rendering to image data, which has undergone image processing and is stored in the second memory device 12 to obtain scan data suitable for the ink jet printing head, a printing apparatus employing such an ink jet printing system can print image data.

Further, the print control device 11 includes a memory capacity calculation device that calculates an amount of image data (e.g. a number of pages) likely stored in the second memory device 12 in accordance with a printing resolution designated by the printing resolution designating device 5, as well as the first memory control device (of the print control device 11) that controls storage of image data in the second memory device 12 in accordance with the calculation result of the memory capacity calculation device. Thus, image data to be printed on the next page can be stored (i.e., taken in) in advance in the second memory device 12 in accordance with the printing resolution and the capacity of the second memory device 12. Thus, a time period necessary for the first data transfer device to transfer image data can be minimized, and accordingly, a processing interval between printings of pages can be minimized even if the image processing device and the storage device each only handles one plate value.

Further, since the print control device 11 includes a second memory control device that repeatedly reads the same image data as needed from the second memory device 12 when the copy number designating device 6 designates prescribed plural numbers of copies, and the image data is transferred to the print control device 17 and is printed on the printing medium in turn as is or via the rendering device 16, the same data does not need to be repeatedly transferred to the first data transfer device 4. Thus, since a time period necessary when image data is transferred by the first data transfer device 4 can be minimized, plurality numbers of copies can be printed while suppressing load on the main control unit 1. Further, even if each of an image processing device and a storage device handles only one plate value, a processing interval between printings of pages can be minimized.

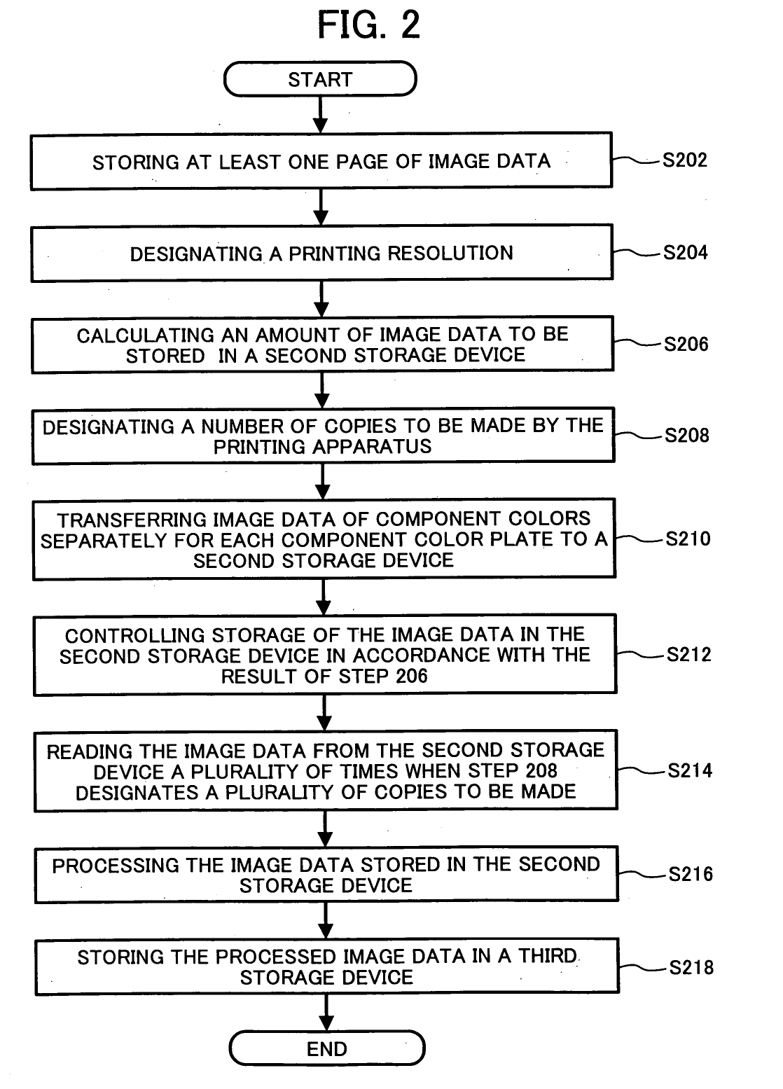

FIG. 2 depicts an exemplary method of controlling a color printing apparatus. In step 202, at least one page of image data is stored in a storage device. Step 204 operates for designating a printing resolution. Step 206 operates for calculating an amount of image data to be stored in a second storage device based upon the resolution. Step 208 operates for designating a number of copies to be made by the printing apparatus. Step 210 operates for transferring image data of component colors separately for each component color plate to a second storage device. Step 212 operates for controlling storage of the image data on the second storage device in accordance with the result of step 206. Step 214 operates for reading the image data from the second storage device a plurality of times when step 208 designates a plurality of copies to be made. Step 216 operates for processing the image data stored in the second storage device. Step 218 operates storing the processed image data in a third storage device.

Processing step 216 may include converting a resolution of the image data into a prescribed level before printing, and recording the image data before printing.

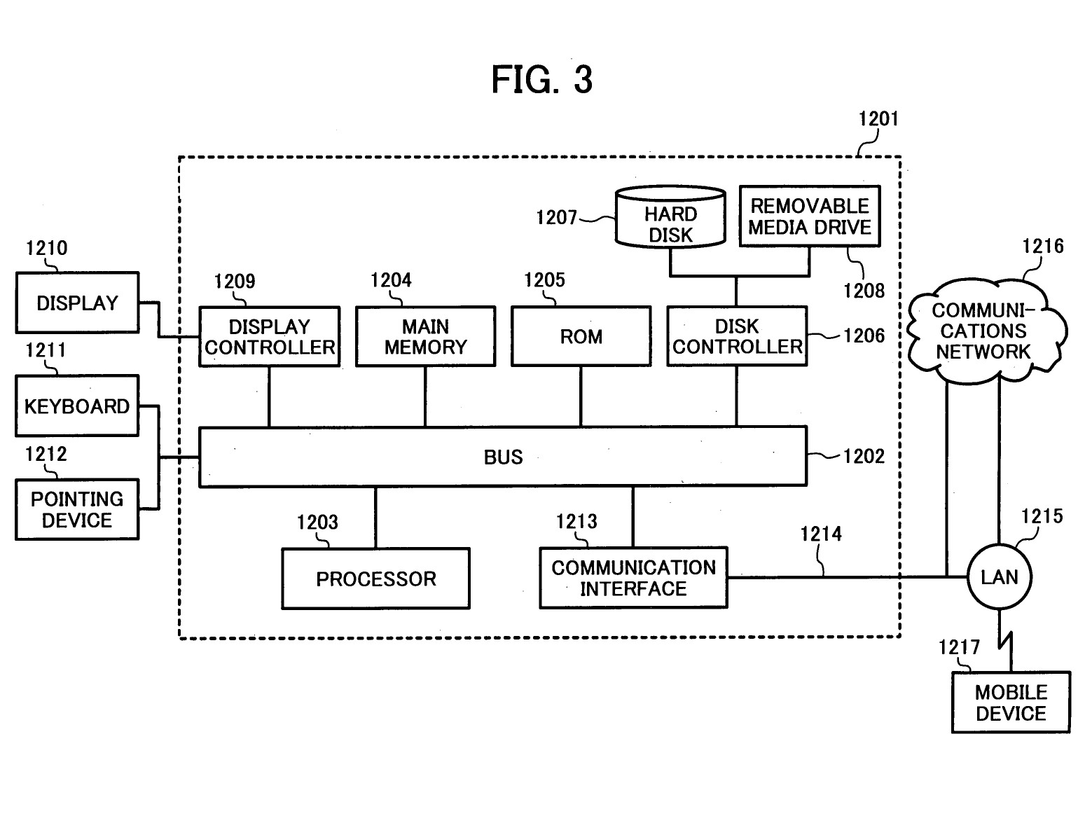

FIG. 3 illustrates a computer system 1201 upon which an embodiment of the present invention may be implemented. The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), synchronous DRAM (SDRAM), etc.), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable ROM (PROM), erasable PROM (EPROM), electrically erasable PROM (EEPROM), etc.) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)).

The computer system 1201 may also include a display controller 1209 coupled to the bus 1202 to control a display 1210, such as a cathode ray tube (CRT), for displaying information to a computer user. The computer system includes input devices, such as a keyboard 1211 and a pointing device 1212, for interacting with a computer user and providing information to the processor 1203. The pointing device 1212 may, for example, be a mouse, a trackball, a pointing stick, etc. for communicating direction information and command selections to the processor 1203 and for controlling cursor movement on the display 1210. In addition, a printer may provide printed listings of data stored and/or generated by the computer system 1201.

The computer system 1201 performs a portion or all of the processing operation of the invention in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the computer system 1201, for driving a device or devices for implementing the invention, and for enabling the computer system 1201 to interact with a human user (e.g., print production personnel). Such software may include, but is not limited to, device drivers, operating systems, development tools, and applications software. Such computer readable media further include the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media include, for example, optical, magnetic disks, and magneto-optical disks, such as the hard disk 1207 or the removable media drive 1208. Volatile media include dynamic memory, such as the main memory 1204. Transmission media include coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the present invention remotely into a dynamic memory and send the instructions over a telephone line using a modem. A modem local to the computer system 1201 may receive the data on the telephone line and use an infrared transmitter to convert the data to an infrared signal. An infrared detector coupled to the bus 1202 can receive the data carried in the infrared signal and place the data on the bus 1202. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card, a modem, etc. to provide a data communication connection to a corresponding type of communications line. Wireless links may also be implemented. In any such implementation, the communication interface 1213 sends and receives electrical, electromagnetic, or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201, may be implemented in baseband signals, or carrier wave based signals. The baseband signals convey the digital data as unmodulated electrical pulses that are descriptive of a stream of digital data bits, in which the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different than baseband, by modulating a carrier wave. The computer system 1201 can transmit and receive data, including program code, through the network(s) 1215 and 1216, the network link 1214, and the communication interface 1213. Moreover, the network link 1214 may provide a connection through a LAN 1215 to a mobile device 1217 such as a personal digital assistant (PDA), laptop computer, or cellular telephone.

The present invention can be applied to a multifunction machine and a copier, if an image reading apparatus such as a scanner is additionally employed.

Numerous additional modifications and variations of the present invention are possible in light of the above teachings. It is therefore to be understood that within the scope of the appended claims, the present invention may be practiced otherwise than as specifically described herein.

1. A color printing apparatus, comprising:
a main control unit including,
a main control device configured to generally control the color printing apparatus;
a first storage device having a capacity to store at least one page of image data, and
a first data transfer device configured to transfer image data of component colors separately for each component color plate; and
a print control unit connected to the main control unit, said print control unit including,
a print control device configured to control printing of a color image on a sheet in accordance with the image data,
a second storage device having a capacity to store at least one page of image data,
an image processing device configured to process the image data, and
a third storage device configured to store the image data having received the image processing.

2. The color printing apparatus, according to claim 1, wherein said image processing device comprises a resolution conversion device configured to convert a resolution of the image data into a prescribed level before printing.

3. The color printing apparatus, according to claim 2, wherein said print control unit comprises a reordering device configured to reorder the image data before printing.

4. The color printing apparatus, according to claim 3, wherein said main control unit comprises:
a print resolution designating device configured to designate a printing resolution, and
wherein said print control device includes,
a memory capacity calculation device configured to calculate an amount of image data to be stored in the second memory based upon the designated print resolution, and
a first storage device control device configured to control storage of the image data in the second storage device in accordance with a calculation result of the memory capacity calculation device.

5. The color printing apparatus, according to claim 4, wherein the main control unit comprises:
a copy number designating device configured to designate a number of copies, and
wherein said print control unit includes,
a second storage device control device configured to read a same color image data from the second storage device as needed when the copy number designating device designates prescribed plural numbers of copies.

6. A method of controlling a color printing apparatus, comprising:
storing at least one page of image data in a first storage device;
transferring image data of component colors separately for each component color plate to a second storage device having a capacity to store at least one page of image data;
processing the image data stored in the second storage device; and
storing the image data that received the processing in a third storage device.

7. The method of claim 6, wherein the processing further comprises:
converting a resolution of the image data into a prescribed level before printing.

8. The method of claim 7, wherein the processing further comprises:
reordering the image data before printing.

9. The method of claim 8, further comprising:
designating a printing resolution;
calculating an amount of image data to be stored in the second storage device based upon the designated print resolution; and
controlling storage of the image data in the second storage device in accordance with a calculation resulting from the calculating.

10. The method of claim 9, further comprising:
designating a number of copies to be made by the printing apparatus; and
reading the image data from the second storage device a plurality of times when the designating designates a plurality of copies to be made.

11. An apparatus for controlling a color printing apparatus, comprising:
means for storing at least one page of image data in a first storage device;
means for transferring image data of component colors separately for each component color plate to a second storage device having a capacity to store at least one page of image data;
means for processing the image data stored in the second storage device; and
means for storing the image data that received the processing in a third storage device.

12. The apparatus of claim 11, wherein the means for processing further comprises:
means for converting a resolution of the image data into a prescribed level before printing.

13. The apparatus of claim 12, wherein the means for processing further comprises:
means for reordering the image data before printing.

14. The apparatus of claim 13, further comprising:
means for designating a printing resolution;
means for calculating an amount of image data to be stored in the second storage device based upon the designated print resolution; and
means for controlling storage of the image data in the second storage device in accordance with a calculation resulting from the means for calculating.

15. The apparatus of claim 14, further comprising:
means for designating a number of copies to be made by the printing apparatus; and
means for reading the image data from the second storage device a plurality of times when the means for designating designates a plurality of copies to be made.

16. A computer program product storing instructions for execution on a computer system, which when executed by the computer system, causes the computer system to perform the method recited in claim 6.
